(19) United States
(12) Patent Application Publication
(10) Pub. No.: US 2021/0392077 A1
(43) Pub. Date: Dec. 16, 2021

(54) Modular Electronic Control Unit for a Motor Vehicle, and Motor Vehicle Having Such a Control Unit and Computing Module Unit for The Control Unit

(71) Applicant: Bayerische Motoren Werke Aktiengesellschaft, Muenchen (DE)

(72) Inventors: Wolfgang LAENGST, Bergkirchen (DE); Reiner STRIEBEL, Reichenau (DE)

(21) Appl. No.: 17/311,160

(22) PCT Filed: Dec. 5, 2019
(86) PCT No.: PCT/EP2019/083771

§ 371 Date: Jun. 4, 2021

(30) Foreign Application Priority Data
Dec. 6, 2018 (DE) 10 2018 131 134.6

(51) Int. Cl. H04L 12/741; G05B 19/042; B60R 16/023; H04L 12/40; H05K 5/00

(52) U.S. Cl. CPC H04L 45/745; G05B 19/0423; B60R 16/0231; B60W 60/00; H05K 5/0065; G05B 2219/2637; H04L 12/40013

(57) ABSTRACT

An electronic control unit for a motor vehicle. A communication unit is arranged in a module housing that is configured to interchange communication data with at least one device-external vehicle component by means of at least one predetermined communication protocol. The communication unit provides a device-internal bus system, in which a controller device of the bus system provides for forwarding of the communication data within the control unit by means of a bus protocol that has an address space that is independent of the at least one communication protocol. The bus system has at least one bus connection for a respective additional computing module unit, different from the communication unit, of the control unit. The at least one bus connection is configured to connect the respective computing module unit to the central module housing from the outside.

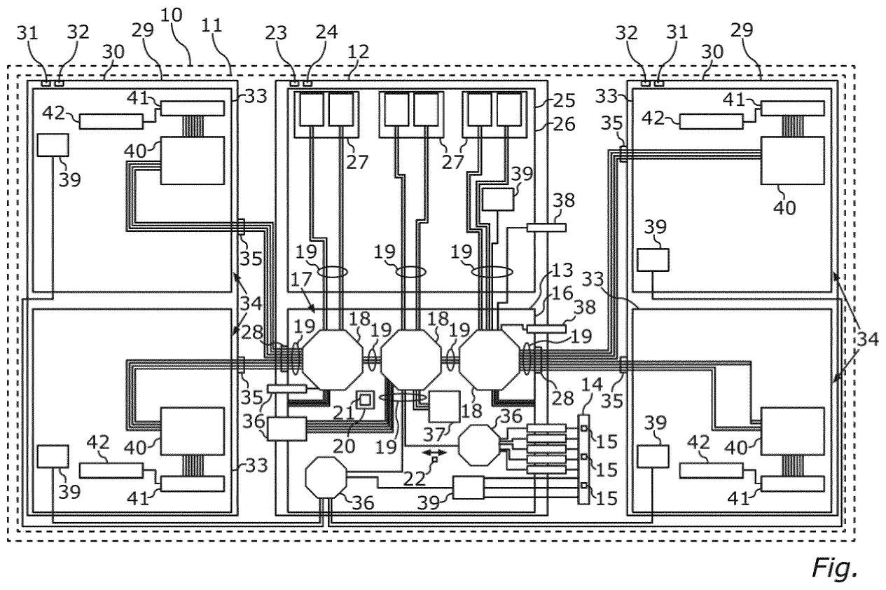

### BACKGROUND AND SUMMARY OF THE INVENTION

The invention relates to an electronic controller for a motor vehicle. The controller has a communication unit by way of which the controller is able to exchange communication data with at least one vehicle component external to the controller, that is to say for example another controller. The invention also includes a motor vehicle having such a controller and a computing module unit that may be provided as part of the controller.

In order to provide a vehicle function, for example a driving function for autonomous driving, in a motor vehicle, provision may be made to implement this vehicle function on the basis of a controller. Such a controller may have at least one processor system that may be provided in a housing together with a suitable power supply for the voltage supply and a cooling apparatus for dissipating waste heat. The desired driving function is then implemented by way of operating software for the at least one processor system, such that, during operation of the controller, when the operating software is executed, the vehicle function is thereby present in the motor vehicle. A “processor system” is understood to mean a circuit board containing at least one microprocessor and the processor peripheral required for the operation of the at least one microprocessor, for example a working memory (RAM—random access memory).

In order, during operation of the controller, that overloading of the at least one processor system does not occur, the computing power of the at least one processor system should be designed such that all of the computing steps that arise during execution of the operating software are able to be executed in timely fashion in order to meet the requirements placed on the vehicle function. In the same way, it is also necessary to dimension the power supply and the cooling apparatus for the at least one processor system in a suitable manner, such that the at least one processor system is able to run in a stable manner.

When implementing a vehicle function, a computing power is thus defined through selection and/or dimensioning of the at least one processor system, and the cooling apparatus and/or the supply of current from the power supply is then dimensioned according thereto.

In the case of a vehicle function, such as in particular the autonomous driving mode, it may however be the case that it is not known in the development phase how much computing power the driving function will ultimately require, since it transpires during the development phase that further additional functions are necessary. It may additionally be of interest to further develop the vehicle function, as a result of which the demand for computing power may also increase. If a new version of a vehicle function is then available and requires more computing power than the controller provided for this vehicle function, that is to say the controller hardware, is currently able to provide, then it is necessary to redesign the controller, which complicates the development of such a vehicle function. The controller is not able to be expanded easily in order to be able to implement new or additional functionalities that require more computing power.

DE 10 2004 022 614 B3 discloses a controller for a motor vehicle that is able to be expanded in terms of its technical configuration by virtue of additional circuits being plugged into the housing of the controller, these additional circuits also having an additional connection option for additional sensors and actuators. The circuits are thus necessary whenever it is desired to connect a special sensor or actuator. It is thus not possible to use such an additional circuit in a flexible manner, since each circuit entails a specific sensor/actuator interface.

DE 10 2008 000 817 A1 discloses a scalable driver assistance system for a motor vehicle, wherein the scalability relates to the number of connectable cameras and the number of interconnected controllers. If more computing power is required, a corresponding number of controllers have to be connected together. This however increases networking expenditure.

DE 10 2012 009 482 A1 discloses a functionally expandable controller into which it is optionally possible to plug multiple application modules that provide functionalities of the controller. Since all of the application modules are arranged in one and the same housing, an air-conditioning system of the controller needs to be designed for the maximum possible number of application modules. However, this may in many cases mean over-dimensioning.

The invention is based on the object of being able to adapt a controller for a motor vehicle to the demand for computing power of a vehicle function in a flexible manner, this vehicle function being intended to be implemented or provided in the motor vehicle by way of the controller.

The object is achieved by the subjects of the independent patent claims. Advantageous embodiments of the invention are described by the dependent patent claims, the following description and the FIGURE.

The invention provides an electronic controller (ECU—electronic control unit) for a motor vehicle. The controller has a housing, which is referred to here as central module housing. A communication unit is arranged in the central module housing and is designed to exchange communication data with at least one vehicle component external to the controller by way of a predetermined communication protocol. “External to the controller” means that the respective vehicle component is not part of the controller, but rather for example constitutes another controller or a sensor unit or an actuator unit. As communication protocol, provision may be made for example for a bus protocol, such as for example for the CAN bus (CAN—Controller Area Network), or a network protocol, such as for example for the Ethernet protocol, or the IP (Internet protocol). Using a communication unit of said type, a processor system of the controller may thus for example exchange communication data, for example state data of the at least one vehicle component and/or control commands for the at least one vehicle component, with said vehicle component, that is to say receive them therefrom and/or transmit them thereto.

In the controller according to the invention, provision is made for a bus system internal to the controller for forwarding or distributing the communication data within the controller through said communication unit. “Internal to the controller” is understood here to mean that bus lines of the bus system extend only within the controller and are not laid outside of the controller, for example up to the at least one vehicle component.

Communication by way of a communication protocol requires addresses in order to identify a sender and/or a receiver of a communication message or of a data packet. A controller apparatus of the bus system is in this case designed to forward said communication data within the controller by way of a bus protocol that differs from the at least one communication protocol in that the address space of the bus protocol is independent of the address space of the at least one communication protocol external to the controller. Within the controller, the communication data in the controller according to the invention are thus transmitted via the bus system in which bus addresses are used, these bus addresses being different from or at least independent of those communication addresses that are used outside the controller when transmitting the communication data between the controller, on the one hand, and the at least one vehicle component, on the other hand. This is because, within the controller, the communication data are transmitted or forwarded by way of the bus system internal to the controller, which bus system is not used for the transmission, external to the controller, of the communication data.

The bus system is used to make the controller scalable in terms of its performance or computing power. For this purpose, provision is made for the bus system to have at least one bus connection for at least one respective additional computing module unit, different from the communication unit, of the controller, and the at least one bus connection is in this case designed to connect the respective computing module unit externally to the central module housing. In other words, bus subscribers are able to connect to the bus system and are then able to transmit or receive the communication data. As bus subscribers, provision may in each case be made for example for a computing module unit or a processor system provided in the computing module unit, which processor system may in each case be connected to a bus connection. This respective bus connection is in this case designed to couple the processor system of the respective computing module unit externally to the central module housing. In other words, at least one additional computing module unit with at least one additional processor system contained therein may be externally connected to the fully designed central module housing. The computing power of the at least one additional computing module unit may thereby then be used in the controller. The communication data to be processed and/or the communication data generated during processing are in this case distributed by way of the communication unit of the central module housing, that is to say transmitted or exchanged between the at least one computing module unit, on the one hand, and the at least one vehicle component external to the vehicle, on the other hand. A single processor system may for example be implemented on the basis of a circuit board and/or an SoC (system on chip).

The invention results in the advantage of providing a controller able to be expanded in a modular manner, in which a respective additional computing module unit is able to be connected or added via at least one bus connection, preferably multiple bus connections, by way of which additional computing module unit additional computing power is then able to be provided in the controller. The central module housing containing the communication unit, once fully designed, in this case no longer has to be redesigned.

The invention also includes embodiments that result in additional advantages.

In at least one embodiment, the controller unit of the bus system is designed to route or to transmit the communication data in the bus system in accordance with a predefined routing table. In other words, the routing table defines the bus subscriber, that is to say for example the computing module unit, to which relevant communication data should be transmitted and/or the vehicle component to which the communication data of a specific computing module unit should be transmitted. This routing table is pre-definable, meaning that the routing or the transmission in the bus system is able to be configured. The routing table may for example be stored in the form of a file or in the form of a data record in the controller. If the controller is changed with regard to the number of connected computing module units, then this may be taken into consideration by adjusting the routing table.

In at least one embodiment, the controller apparatus is designed to perform address assignment (also called address mapping) between a respective communication address, which is predefined in accordance with the at least one communication protocol (for the data exchange external to the controller), on the one hand, and a respective bus address of the address space of the bus system, on the other hand. In other words, a communication address for the at least one communication protocol external to the controller may be mapped onto a respective corresponding bus address of the bus system. The communication addresses for the communication external to the controller (exchange of the communication data) are thus mapped onto the address scheme of the bus system. This is performed by the controller unit, meaning that the bus system thus remains transparent during the communication for the bus subscribers of the bus system and/or for the at least one vehicle component external to the controller. It is therefore not necessary to adjust the at least one vehicle component external to the controller when one embodiment of the controller is intended to be installed in a motor vehicle.

In at least one embodiment, the controller apparatus of the bus system is designed to perform dynamic address allocation of a respective bus address for a respective bus subscriber internal to the controller and connected to the bus system upon starting upon respective starting of the controller. In other words, the address space is managed or configured automatically by the controller apparatus. The controller may thereby be retrofitted, and an unambiguous allocation of bus addresses to bus subscribers still takes place.

As already explained, the bus system is independent of the communication technology that may be provided externally to the controller and to which the controller may be connected. In other words, there is thus in particular provision for the bus system internal to the controller to be based on a bus protocol different from the at least one communication protocol external to the controller. It has proven particularly advantageous here for the bus system to be provided on the basis of a PCIe technology (PCIe—Peripheral Component Interconnect Express). This offers the bandwidth for transmitting communication data as is required in a controller, in particular for communication data for providing an autonomous driving function.

In at least one embodiment, the at least one computing module unit has a respective dedicated module housing. The central module housing and the respective module housing of the at least one additional computing module unit in this case each have a dedicated power supply (that is to say a dedicated supply of current and/or voltage stabilization) and/or a dedicated cooling apparatus. In other words, each module housing may thus be operated independently of every other module housing in terms of energy supply and/or cooling. If an additional computing module unit is thus connected to the central module housing in which the communication unit is located, then this does not result in any additional loading of the power supply and/or of the cooling apparatus of the central module housing. Each computing module unit instead contributes its own power supply and/or its own cooling apparatus. No redesigning whatsoever of the hardware of the central module housing is thus necessary when expanding the controller with a further computing module unit. It is then necessary only to incorporate or to integrate the newly added computing module unit into the data communication with regard to the communication data, for example by predefining a new routing table, such that those communication data that are provided for the new computing module unit are transmitted thereto via the bus system.

In at least one embodiment, the at least one computing module unit has a single processor system that is added to the controller by an adjoining computing module unit. In another embodiment, on the other hand, there is provision for the at least one computing module unit to have respective installation spaces for multiple processor systems, and each installation space of the computing module unit is designed to connect the processor system of this installation space to the bus system individually, that is to say independently of every other processor system of the computing module unit. In other words, through the bus connection of the bus system to which a computing module unit is connected, it is thus possible to incorporate more than one processor system into the controller or integrate same into the controller. In this case, however, each processor system is connected independently. This results in the advantage that, in the computing module unit, each processor system is able to be operated independently of whether all of the installation spaces are occupied. The computing power is thus likewise able to be scaled within the computing module unit by specifying how many processor systems are installed or provided in the computing module unit. Each installation space offers an independent connection option for connecting a processor system to the bus system, that is to say for example a connection between the circuit board of the processor system and the bus connection at the central module housing.

In at least one embodiment, at least one basic processor system is already arranged in the central module housing and is designed to provide a vehicle function, that is to say to generate said communication data (for transmitted communication data) and/or to process them (for received communication data), independently of an additional computing module unit, that is to say that an additional computing module unit is connected at a bus connection. In other words, the controller may also be put into service solely on the basis of the central module housing. For this purpose, a basic computing power is provided in the central module housing on the basis of the at least one basic processor system. If the controller is intended for example for an autonomous driving function, then the image processing required in each case, that is to say “computer vision processing”, may for example be implemented in the central module housing. If the intention is then to provide additional functionalities for the autonomous driving function, for example object classification of detected objects, then the computing power required for this purpose may be added or connected by way of at least one additional computing module unit in the controller.

In at least one embodiment, the at least one computing module unit is consequently considered to be an expansion internal to the controller, by virtue, in the controller, of the at least one computing module unit having a data connection to the peripheral external to the controller, that is to say in particular to the at least one vehicle component, solely via the communication unit in the central module housing. The at least one computing module unit thus does not have any dedicated communication connection to the peripheral external to the controller that would bypass the central module housing, in particular its communication unit.

In at least one embodiment, the controller apparatus of the bus system is designed to operate or to use at least one of the following as the at least one communication protocol: Ethernet, at least one data bus protocol, in particular CAN and/or LIN (Local Interconnect Network), sensor communication with at least one sensor unit, in particular a camera and/or a radar. Common communication connections to a peripheral external to the controller may thus be supported or operated in the controller by way of the controller apparatus. No complex adjustment of the software is necessary for the at least one computing module unit, since the actual communication may already be supported by the controller apparatus.

In at least one embodiment, more than one bus connection for a respective computing module unit is provided. By way of example, two bus connections may be provided. In one embodiment, provision is made here for the controller unit to be designed also to perform data transmission internal to the controller and/or a DMA transfer (DMA—direct memory access) internal to the controller between the different bus connections, that is to say between different computing module units, via the bus system. In other words, the controller unit is designed also to connect the processor systems to one another for a data exchange or a data transmission. In the DMA transfer, the memory content of a data memory, in particular of a RAM (random access memory), is in this case copied from a processor system to a data memory, in particular a RAM, of another processor system by the controller apparatus after one of the processor systems has initiated or triggered this data transmission. Inter-process communication across the bus system is thereby possible, for example. This speeds up the coordination and/or the interaction between program processes that run or are executed on different processor systems.

In at least one embodiment, the controller has operating software for an autonomous driving function of the motor vehicle. The controller is in this case designed to provide the autonomous driving function during operation by way of the operating software. In other words, the controller is part of an autopilot system. By way of example, the controller may implement surroundings detection on the basis for example of at least one camera and/or at least one radar and/or at least one lidar.

The invention also comprises the motor vehicle that has at least one embodiment of the controller according to the invention. The motor vehicle according to the invention may for example be an automobile, that is to say for example a passenger car or a truck. The motor vehicle may also be a motorcycle.

In order to be able to expand the controller according to the invention in a modular manner, the described computing module unit for the controller is necessary. The invention accordingly also comprises such a computing module unit having a module housing that has a connection apparatus for connecting the computing module unit to a bus connection of a bus system of a central module housing of the controller. At least one processor system is also provided in the module housing of the computing module unit. The controller may thus be expanded with the at least one processor system by way of the computing module unit by virtue of the connection apparatus of the computing module unit being connected to a bus connection of the bus system of the central module housing. The connection apparatus may for example provide a plug connection in order to be able to plug the module housing of the computing module unit onto the central module housing. In addition or as an alternative thereto, provision may be made for a mechanical connection, for example by way of a screw connection and/or a latching connection.

The invention also comprises embodiments of the computing module unit having those additional features as have already been described in connection with the embodiments of the controller according to the invention. These additional features are therefore not described again here.

Further features of the invention become apparent from the claims, the figures and the description of the figures. The features and combinations of features mentioned above in the description and the features and combinations of features mentioned below in the description of the figures and/or shown only in the figures may be used not only in the respectively specified combination, but also in other combinations or on their own.

### BRIEF DESCRIPTION OF THE DRAWING

The invention is now explained in more detail on the basis of one preferred exemplary embodiment and with reference to the drawing.

The single FIGURE shows a schematic illustration of aspects of at least one embodiment of the motor vehicle according to the invention.

### DETAILED DESCRIPTION OF THE DRAWING

In the FIGURE, identical reference signs each denote functionally identical elements.

The FIG. shows a motor vehicle 10. The motor vehicle 10 may be designed as an automobile, for example a passenger car or truck, or as a motorcycle. A controller 11 may be provided in the motor vehicle 10. The controller 11 may provide a vehicle function in the motor vehicle 10, for example a driving function for autonomous driving (autonomous driving function).

In order, in the case of developing the vehicle function, to be able to flexibly adjust the hardware of the controller 11, that is to say to be able to cover an increasing demand for computing power in the case of expanding the vehicle function, the controller 11 may be of modular design.

The controller 11 may for this purpose have a central module housing 12 in which provision may be made for a communication unit 13 by way of which it is possible to perform a data exchange of communication data 22 with the peripheral 14 external to the controller and additionally also a data exchange internal to the controller. The peripheral 14 external to the controller may comprise at least one vehicle component 15 of the motor vehicle 10, for example at least one other controller and/or at least one sensor. The communication unit 13 may for example be formed on the basis of a circuit board 16.

The communication unit 13 may provide or operate a bus system 17 for the data transmission, internal to the controller, in the controller 11. The bus system 17 may for example have at least one data switch or a switch 18. The FIGURE illustrates three switches A, B, C by way of example. The bus system may for example be a PCIe bus system. Data lines 19 of the bus system 17 are illustrated in the FIGURE in order to show communication paths. Not all of the data lines are provided with a reference sign for the sake of clarity.

A controller apparatus 20 of the bus system 17 may be designed to dynamically assign a bus address to the bus subscribers connected to the bus system 17 upon starting of the controller 11 in order to be able to unambiguously address each bus subscriber. There may additionally be provision to predefine, by way of a routing table 21 of the controller apparatus 20, how communication data 22 should be routed or assigned in the bus system 17. The controller apparatus 20 may be provided in the form of at least one integrated circuit.

A power supply 23 for a supply of current and/or a cooling apparatus 24 for dissipating waste heat may be provided in the central module housing 12 for the operation of the communication unit 13. The module housing 12 may thus be connected to an electrical energy supply of the motor vehicle 10, for example an electrical on-board power system, and then operate the communication unit 13 in the central module housing 12.

At least one basic processor system 25 may be provided in the central module housing 12 in addition to the communication unit 13, which basic processor system may for example be based on a dedicated circuit board 26. The at least one basic processor system 25 may implement or perform a basic functionality of the controller 11. For this purpose, provision may be made for example for at least one computing unit 27 that is able to execute operating software or a portion of operating software of the controller 11. By way of example, the basic processor system 25 may implement or perform image processing, that is to say computer vision processing.

In order then to be able to expand a computing power beyond the at least one basic processor system 25, the bus system 17 may have at least one bus connection 28 to which a respective additional computing module unit 29 may be connected. Each computing module unit 29 may have a dedicated module housing 30 in which a respective dedicated power supply 31 and/or a dedicated cooling apparatus 32 may be provided. In each case one or more than one dedicated processor system 33 may be provided in each computing module unit 29, that is to say at least one installation space 34 for a respective processor system 33 may be located in each module housing 30. In this case, provision may be made, in each computing module unit 29, for a connection apparatus 35 via which the respective processor system 33 of the computing module unit 29 is able to be connected individually, that is to say independently of every other processor system 33 of the same computing module unit 29, to the bus connection 28 of the bus system 17 in the central module housing 12. It is thus also possible to connect a computing module unit 29 to multiple installation spaces 34, in the case of which however not all of the installation spaces 34 have to be occupied or equipped with a respective processor system 33.

By virtue of the respective dedicated power supply 31 and/or the respective dedicated cooling apparatus 32 in each computing module unit 29, connecting a computing module unit 29 to the central module housing 12 does not constitute any additional loading for the power supply 23 and/or the cooling apparatus 24.

The two bus connections 28 that are illustrated are only examples. It is possible to provide a single bus connection 28, or it is possible to provide more than two bus connections 28 in the controller 11.

By virtue of the controller apparatus 20, communication data 22 may in this case be transmitted between the processor systems 25, 23 and between the basic processor systems 25, 33, on the one hand, and connection controllers 36 for the peripheral 14, that is to say for the at least one vehicle component 15 or the external bus systems leading thereto, on the other hand. This is achieved in particular by tunneling, that is to say the conversion or translation of communication addresses for the communication external to the controller, on the one hand, and bus addresses of the bus system 17, on the other hand, may be performed independently by the controller apparatus 20.

Provision may be made for connection controllers 36 for the connection of a bus network (for example CAN and/or LIN) and/or at least one radar sensor and/or at least one camera and/or at least one lidar and/or at least one microphone array and/or at least one fallback controller. The bus system 17 may also supply a logging apparatus 37 with logging data.

Provision may be made for a direct readout connection 38 for reading out debugging data from the bus system 17.

A respective monitoring circuit 39 may be provided for each processor system 25, 33, which monitoring circuit is able to provide what is known as a heartbeat functionality, for example. If there is a defect in a processor system 25, 33, then the monitoring circuit 39 of this processor system 25, 33 may signal this. Routing of the communication data 22 and/or of the data transmission internal to the controller may be adjusted in response, for example by the controller apparatus 20, in order to replace the software function of the defective processor system 25, 33 with at least one other processor system 25, 33 that is still functional.

The FIGURE additionally shows how functional monitoring 42, independent of the actual microprocessor arrangement 40, is able to monitor a functionality and/or plausibility of the function of the processor system 33, for each processor system 33 of a computing module unit 29 via a communication chip 41, in addition to the actual microprocessor arrangement 40. A security level of the processor system 33 may thereby for example be raised to the ASIL-D level.

In the controller 11, splitting or dividing the provided vehicle function over multiple separate computing module units and coupling or linking the computing module unit by way of the communication unit, in particular based on PCIe technology, allows the computing power of the controller 11 to be expanded in a modular manner. Using the PCIe technology guarantees a sufficient bandwidth, abstraction and expansion capability. Provision may preferably be made for two to five independent computing module units 29 each having a dedicated module housing 30, a dedicated supply of current provided by a dedicated power supply 31 and cooling provided by a dedicated cooling apparatus 32.

The computing module apparatuses are preferably connected to the communication unit of the central module housing via PCIe and are thus part of the controller. The controller thus becomes expandable in a modular manner such that any expansion through a respective computing module unit is able to contribute its own supply of current and cooling.

### LIST OF REFERENCE SIGNS

10 motor vehicle
11 controller
12 module housing
13 communication unit
14 peripheral
15 vehicle component
16 circuit board
17 bus system
18 switch
19 data lines
20 control apparatus
21 routing table
22 communication data
23 power supply
24 cooling apparatus
25 basic processor system
26 circuit board
27 computing unit
28 bus connection
29 computing module unit
30 module housing
31 power supply
32 cooling apparatus
33 processor system
34 installation space
35 connection apparatus
36 connection controller
37 logging apparatus
38 readout connection
39 monitoring circuit
40 microprocessor arrangement
41 communication chip
42 function monitoring

1-15. (canceled)

16. An electronic controller for a motor vehicle, the electronic controller comprising:
a central module housing; and
a communication unit that is arranged in the module housing and is designed to exchange communication data with at least one vehicle component external to the controller via at least one predetermined communication protocol,
wherein the communication unit provides a bus system internal to the controller,
wherein a controller apparatus of the bus system is configured to forward the communication data within the controller via a bus protocol that has an address space independent of the at least one communication protocol,
wherein the bus system has at least one bus connection for a respective additional computing module unit, different from the communication unit, of the controller, and
wherein the at least one bus connection is configured to connect the respective computing module unit externally to the central module housing.

17. The controller of claim 16, wherein the controller apparatus is configured to route the communication data in the bus system in accordance with a predefined routing table.

18. The controller of claim 16, wherein the controller apparatus is configured to perform address assignment between a respective communication address, which is predefined in accordance with the at least one communication protocol, and a respective bus address of the address space of the bus system.

19. The controller of claim 16, wherein the controller apparatus is configured to perform dynamic address allocation of a respective bus address from the address space of the bus system to a respective bus subscriber, internal to the controller and connected to the bus system upon respective starting of the controller, of the bus system during the respective starting.

20. The controller of claim 16, wherein the bus system is based on a bus protocol different from the at least one communication protocol.

21. The controller of claim 16, wherein the bus system is provided on the basis of a PCIe technology.

22. The controller of to claim 16,
wherein the at least one computing module unit has a respective dedicated module housing, and
wherein the central module housing and the respective module housing of the at least one computing module unit each have a dedicated electric power supply and/or a dedicated cooling apparatus.

23. The controller of claim 16, wherein each of the at least one computing module unit has respective installation spaces for multiple processor systems, and each installation space of the respective computing module unit connects the processor system of the installation space to the bus system independently of every other processor system of the computing module unit.

24. The controller of claim 16, wherein at least one basic processor system is provided in the central module housing, which basic processor system is configured to generate and/or to process the communication data without a connected additional computing module unit.

25. The controller of claim 16, wherein, in the case of the controller, a data connection to a peripheral external to the controller is provided solely via the communication unit of the central module housing for the at least one computing module unit.

26. The controller of claim 16, wherein the controller apparatus of the communication unit is configured to operate at least one of the following, as the at least one communication protocol: Ethernet, at least one data bus protocol, in particular CAN and/or LIN, and sensor communication with at least one of: a camera, a radar and/or a lidar sensor unit.

27. The controller of claim 16,
wherein more than one bus connection is provided for a respective computing module unit, and
wherein the controller unit is configured to perform data transmission internal to the controller and/or a DMA transfer internal to the controller between the bus connections via the bus system.

28. The controller of claim 16, wherein the controller has operating software for an autonomous driving function of the motor vehicle and is configured to provide the autonomous driving function during operation by way of the operating software.

29. A motor vehicle having at least one controller according to claim 16.

30. A computing module unit comprising:
the controller of claim 16;
a module housing that includes at least one processor system; and
a connection apparatus for connecting the computing module unit to a bus connection of a bus system of a central module housing of the controller.
